(19) United States
(12) Patent Application Publication
(10) Pub. No.: US 2014/0357050 A1
(43) Pub. Date: Dec. 4, 2014

(54) METHOD OF FORMING ISOLATING STRUCTURE AND THROUGH SILICON VIA

(71) Applicant: UNITED MICROELECTRONICS CORP., Hsin-Chu City (TW)

(72) Inventors: JI FENG, Singapore (SG); XIAOQING XU, Singapore (SG); Hailong Gu, Singapore (SG); Ying-Tu Chen, Singapore (SG); JINGLING WANG, Singapore (SG)

(21) Appl. No.: 13/907,996

(22) Filed: Jun. 3, 2013

(51) Int. Cl. H01L 21/762; H01L 21/768

(52) U.S. Cl. CPC H01L 21/76229; H01L 21/76898
USPC 438/430

(57) ABSTRACT

A method of forming an isolation structure and a through silicon via includes the following steps. First, at least a first trench and at least a second trench are formed in the substrate by a single etch step. Then, an insulating layer is formed to simultaneously fill up the first trench and cover a sidewall and a bottom of the second trench. After that, a conductive layer is formed to fill in the second trench. Subsequently, the insulating layer and the conductive layer on a front side of the substrate are removed. Later, a back side of the substrate is thinned to expose the conductive layer in the second trench. The insulating layer in the first trench serves as an insulating filling, and the insulating layer on the sidewall of the second trench serves as a liner of the through silicon via.

### BACKGROUND OF THE INVENTION

1. Field of the Invention

The present invention relates to a method of forming an isolating structure and a through silicon via (TSV), and more particularly, to a method of combining fabrication steps for forming a TSV and a deep trench isolation (DTI).

2. Description of the Prior Art

In modern society, integrated circuits (IC) are utilized in diverse fields such as automatic control electronics, mobile communication devices and personal computers. With the development of technology and the increasingly imaginative applications of electrical products, IC devices are becoming smaller, more sophisticated and more diversified.

Integrated circuits are typically fabricated by sequentially depositing insulating or dielectric layers, conductive layers, and semiconductive layers over a semiconductor substrate, and patterning the various layers using lithography to form circuit components and elements thereon. Some elements are isolated from adjacent circuits by isolators. For example, transistors and other devices may be separated by deep trench isolation structures.

In order to increase the efficiency of the chip by accommodating more IC components in a limited space, many semiconductor package technologies are built up by stacking each die and/or chip. Examples of this include Flip-Chip technology, Multi-chip Package (MCP) technology, Package on Package (PoP) technology and Package in Package (PiP) technology. Besides these technologies, a “Through Silicon Via (TSV)” technique has been developed in recent years. The TSV technology can improve the interconnections between chips in the package, which increases the package efficiency.

The TSV technique creates a shorter interconnection route between chips. Thus, in comparison to other technologies, TSV has the advantages of faster speed, less noise and better efficiency, and is therefore a promising technology.

### SUMMARY OF THE INVENTION

One of the objectives of the present invention is to integrate the fabricating process of the TSV and DTI, and to decrease the number of fabricating steps therein.

According to one embodiment of the present invention, a method of forming a via and an isolating structure comprises providing a substrate having a front side and a back side and at least one shallow trench isolation embedded in the substrate. Then, at least one first trench and at least one second trench are both formed to extend from the front side into the substrate. An insulating layer fills up the first trench and conformally covers a sidewall and a bottom of the second trench. After that, a conductive layer is formed in the second trench and covers the insulating layer. Finally, the back side of the substrate is thinned to expose the conductive layer through the back side so as to form a through silicon via.

According to another embodiment of the present invention, a method of forming a via and an isolating structure comprises providing a substrate having a front side and a back side. At least one first trench and at least one second trench are both formed to extend from the front side into the substrate. Subsequently, an insulating layer is formed to fill up the first trench and conformally cover a sidewall and a bottom of the second trench. After that, a conductive layer is formed in the second trench and covers the insulating layer. Then, a circuit layer is formed on the front side of the substrate. Finally, the back side of the substrate is thinned to expose the conductive layer through the back side to form a through silicon via.

The fabricating steps of the deep trench isolation and the through silicon via are integrated together in the present invention. More particularly, the insulating filling in the deep trench isolation, and the liner for the through silicon via are formed simultaneously by the same step. In this way, better producing efficiency can be reached.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 10 are schematic cross-sectional diagrams illustrating a method of forming an insulating structure and a through silicon via according to a preferred embodiment of the present invention.

### DETAILED DESCRIPTION

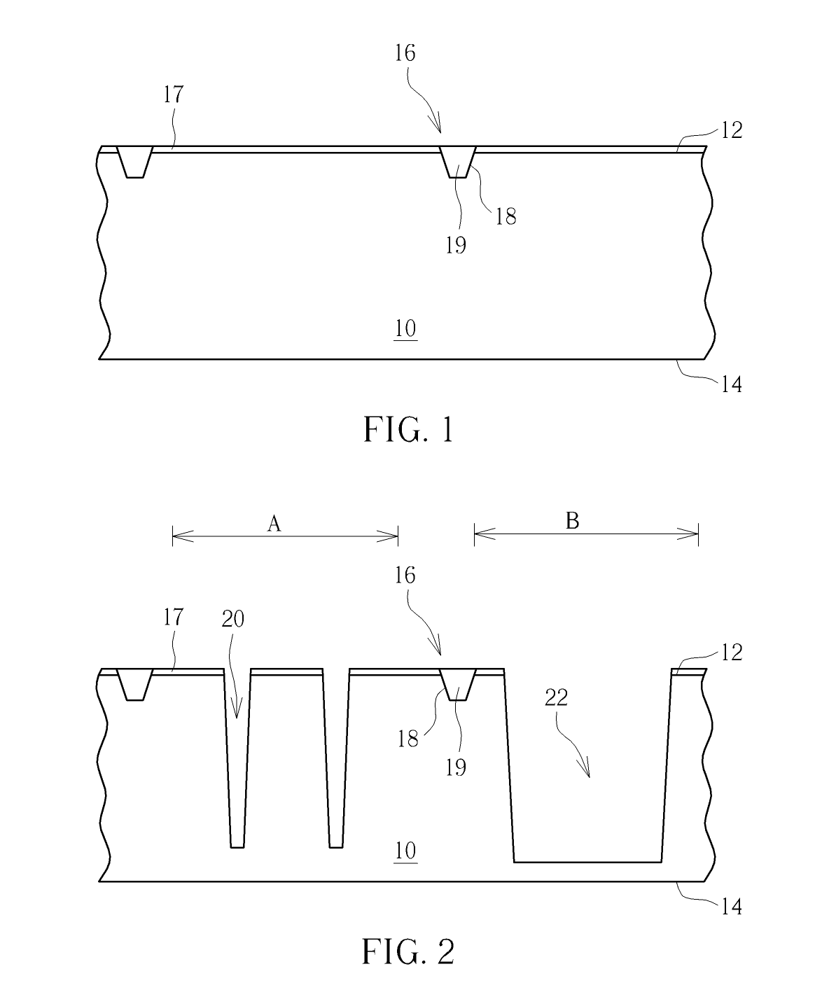

Please refer to FIG. 1 to FIG. 10, which are schematic cross-sectional diagrams illustrating a method of forming an insulating structure and a through silicon via according to a preferred embodiment of present invention. As shown in FIG. 1, a substrate 10 including a front side 12 and a back side 14 is provided. The substrate 10 may be monocrystalline silicon, gallium arsenide, GaAs or other semiconductive substrate. At least one shallow trench isolation (STI) 16 is formed in the substrate 10; more particularly, the STI 16 extends from the front side 12 into the substrate 10, and is for defining element regions. The fabricating steps of the STI 16 include forming a pad oxide layer (not shown), and a pad nitride layer 17 covering the front side 12 of the substrate 10. Then, the pad oxide layer and the pad nitride layer 17 are patterned. After that, the substrate 10 is etched to form at least one shallow trench 18 extending from the front side 12 into the substrate 12 by taking the patterned pad oxide layer and the patterned nitride layer 17 as masks. The depth of the shallow trench 18 is preferably 0.2 μm˜1 μm. Subsequently, an STI liner (not shown) and an insulating layer 19 is formed in the shallow trench 18 in sequence. Please refer to FIG. 2. The pad nitride layer 17 and the aforesaid pad oxide layer are patterned again. Later, the substrate 10 is etched to form at least one first trench 20 and at least one second trench 22 both extending from the front side 12 into the substrate 10 by taking the patterned pad nitride layer 17 and the pad oxide layer as masks. The first trench 20 is for forming a DTI, and the second trench 22 is for forming a TSV afterwards. The fabricating steps of the first trench 20 and the second trench 22 may be performed by utilizing an etch process combining a mask having different opening sizes to etch the substrate 10 and form the first trench 20 and the second trench 22 with different depths in a single dry etch process. More specifically, the first trench 20 and the second trench 22 can be formed by dry etching a first trench predetermination region A and a second trench predetermination region B defined on the substrate 10. During the single dry etch process, the first trench predetermination region A and the second trench predetermination region B on the substrate 10 are both dry etched continuously until the first trench 20 and the second trench 22 are completed simultaneously in the first trench predetermination region A and the second trench predetermination region B. At this point, the single dry etch process is stopped. According to a preferred embodiment of the present invention, the width of the first trench 20 is about 0.1 μm˜3 μm, and the depth of the first trench 20 is about 1 μm˜5 μm. The width of the second trench 22 is about 1 μm˜100 μm, and the depth of the second trench 22 is about 2 μm˜200 μm. In addition, the depths of the first trench 20 and the second trench 22 are both greater than that of the shallow trench 18. The width of the second trench 22 is larger than the width of the first trench 20. More specifically speaking, the width of the second trench 22 is preferably 3 times larger than the width of the first trench 20.

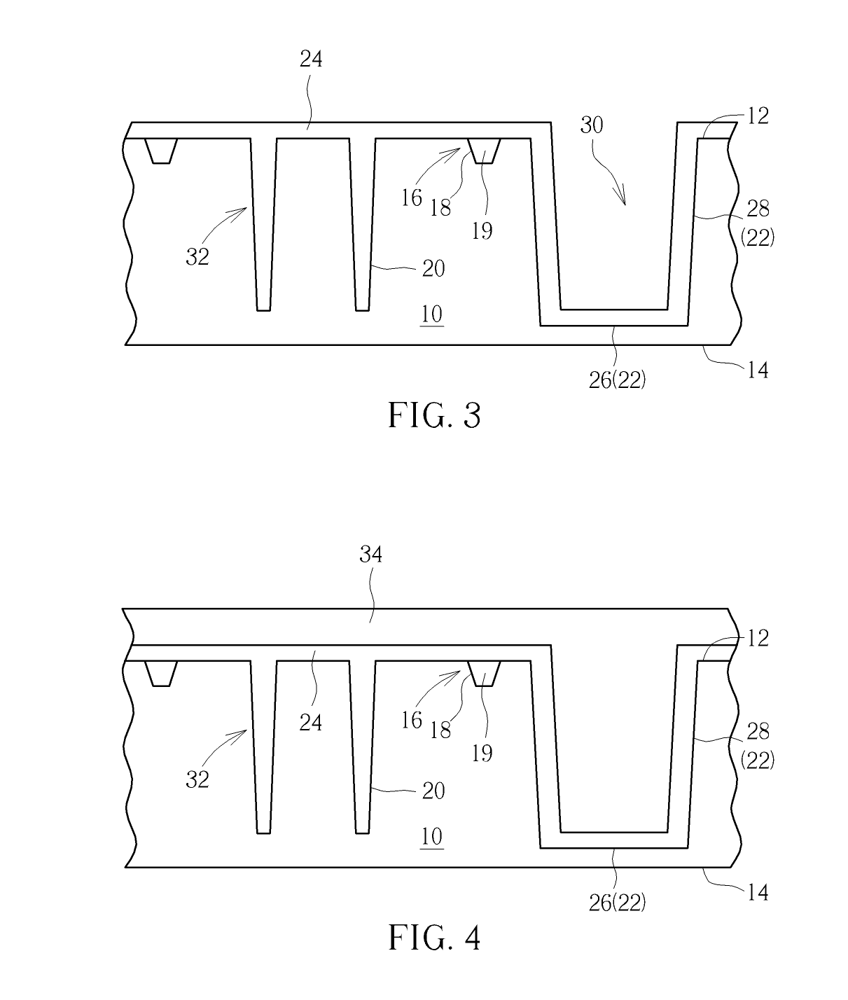

As shown in FIG. 3, the pad nitride layer 17 is optionally removed. Then, an insulating layer 24 is blankly formed. Because the width of the first trench 20 and the second trench 22 are different, the blankly formed insulating layer 24 can fill up the first trench 20 and, at the same time, conformally cover a bottom 26 and a side wall 28 of the second trench 22. After the insulating layer 24 fills up the first trench 20, a DTI 32 is completed. The DTI 32 is preferably used to subsequently define a pixel region. After the insulating layer 24 covers the side wall 28 and the bottom 26 of the second trench 22, a space 30 will remain in the second trench 22. Moreover, the insulating layer 24 also covers the front side 12 of the substrate 10. According to a preferred embodiment of the present invention, the insulating layer 24 may include silicon oxide, silicon nitride, silicon oxynitride or other insulating materials, and the insulating layer 24 may be formed by a single layer or a composite layer. The insulating layer 24 in the DTI 32 serves as an insulating filling, and the insulating layer 24 in the second trench 22 will later become a liner of a TSV. The liner is to electrically isolate the TSV from the substrate 10. It is note worthy that the insulating filling of the DTI 32 and the liner in the second trench 22 are formed in the same step and by the same material.

Please refer to FIG. 4. A conductive layer 34 is formed to cover the insulating layer 24 and fill up the space 30 in the second trench 22. The conductive layer 34 can be doped polysilicon, metal, metal compound or other conductive materials. As shown in FIG. 5, the conductive layer 34 on the front side 12 of the substrate 10 is removed by chemical mechanical polishing or other suitable methods, and only the conductive layer 34 in the second trench 22 will remain. In other words, the conductive layer 34 is only disposed in the second trench 22. The insulating layer 24 on the front side 12 of the substrate 10 can also be optionally removed during the removal of the conductive layer 34 on the front side 12 of the substrate 10. FIG. 5 and subsequent figures show the insulating layer 24 is removed from the front side 12 as an example. The insulating layer 24 on the front side 12 can be kept, however, based on different requirements.

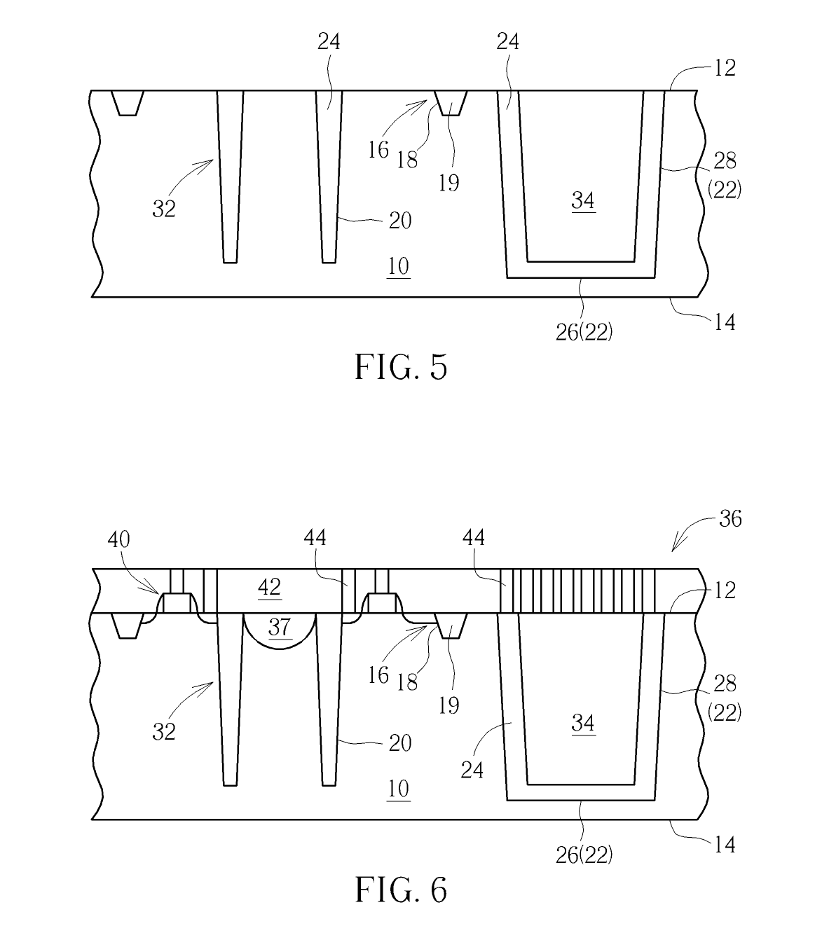

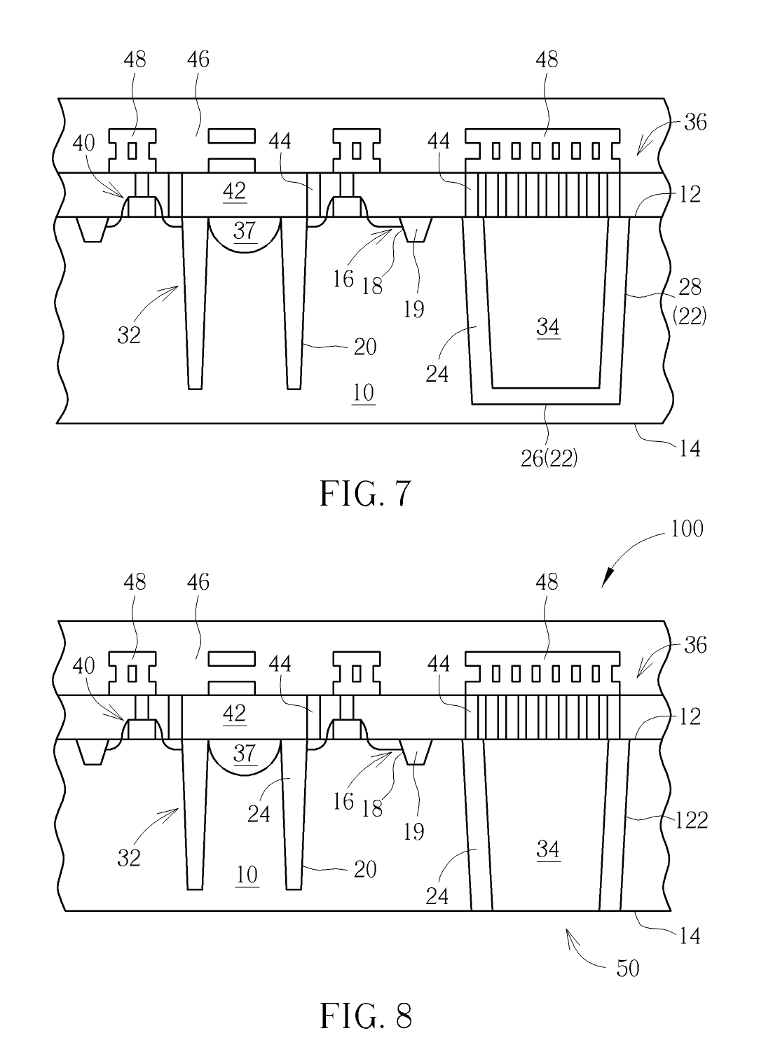

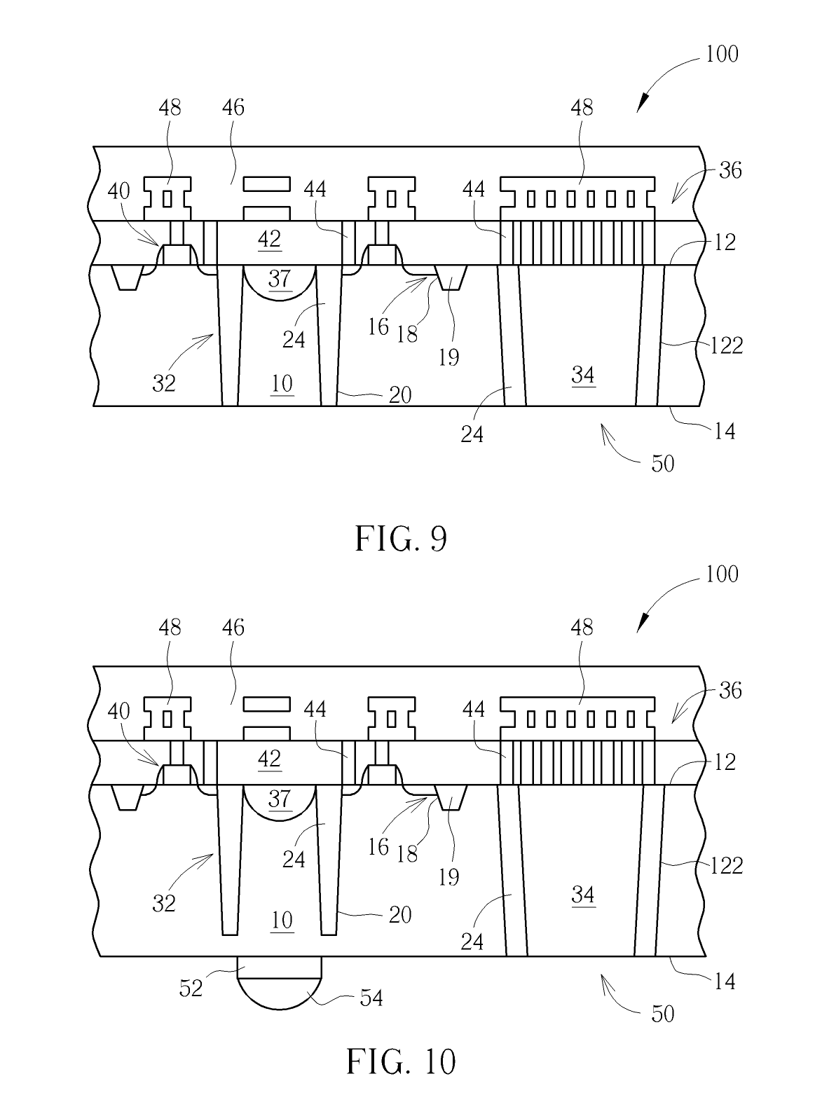

As shown in FIG. 6, a circuit layer 36 and a pixel region 37 are formed at the front side 12 of the substrate 10. The fabricating steps of the circuit layer 36 include forming at least one transistor 40 or other elements on the front side 12 of the substrate 10. Then, an interlayer dielectric 42 is formed to cover the substrate 10 and the transistor 40. Later, numerous contact plugs 44 are formed to penetrate the interlayer dielectric 42. Several contact plugs 44 electrically contact the transistor 40 and the rest of the contact plugs 44 electrically contact the conductive layer 34. During the implantation process for forming a source and a drain of the transistor 40, the pixel region 37 can also be formed by implanting dopants into the front side 12 of the substrate along with the source or drain. After the source and the drain are formed, an anneal process is applied to diffuse the source and the drain. The anneal process is performed at a high temperature, therefore it is better to utilize doped polysilicon as the conductive layer 34 owing to the doped polysilicon having a smaller coefficient of thermal expansion compared with metal. Using doped polysilicon as the conductive layer 34 can therefore prevent the conductive layer 34 from deformation during the anneal process. Please refer to FIG. 7. An inter-metal dielectric 46 is formed to cover the interlayer dielectric 42. Subsequently, a redistribution conductive layer 48 can be optionally formed in the inter-metal dielectric 46, and the redistribution conductive layer 48 connects electrically to the contact plugs 44. As shown in FIG. 8, the back side 14 of the substrate 10 is thinned to expose the conductive layer 34 from the back side 14, and a TSV 50 is completed. After the back side 14 is thinned, the bottom 26 of the second trench 22 is removed and the second trench 26 becomes a through hole 122. According to a preferred embodiment of the present invention, if the conductive layer 34 is doped polysilicon, the doped polysilicon can be replaced by metal by removing the doped polysilicon from the back side 14 of the substrate 10, and filling the metal into the through hole 122. After the thinning step, the thickness of the substrate 10 is preferably 3 micrometers. In addition, because the depth of the second trench 22 is greater than that of the first trench 20, when thinning the back side 14 of the substrate 10, the TSV 50 will be exposed from the back side 14 in advance of the DTI 32. Then, as shown in FIG. 9, the thinning process can be continued optionally until the DTI 32 is exposed from the back side 14. As shown in FIG. 10, in continuous from FIG. 8, at least one color filter 52 and at least one microlens 54 can be formed on the back side 14 of the substrate 10 which corresponds to the pixel region 37. In addition, elements such as high voltage devices or memory devices may be formed on the TSV 50.

A semiconductive element with DTI and TSV is provided according to a preferred element of the present invention. Please refer to FIG. 8, which illustrates a semiconductive element with DTI and TSV 100 including a substrate 10 having a front side 12 and a back side 14. The thickness of the substrate 10 is preferably 3 micrometers, but the structure is not limited herein. At least one DTI 32 extends from the front side 12 into the substrate 10, and the bottom of the DTI 32 may stay in the substrate 10. Alternatively, the DTI 32 may penetrate the substrate 10 as shown in FIG. 10. Please continue to refer to FIG. 8. The semiconductive element with DTI and TSV 100 further comprises a TSV 50 penetrating substrate 10. The DTI 32 includes a first trench 20 and an insulating layer 24 filling up the first trench 20. The TSV 50 includes a through hole 122 and the aforesaid insulating layer 24 fills in the through hole 122 to serve as a liner. The insulating layer 24 surrounds and covers a sidewall of the through hole 122. Furthermore, a conductive layer 34 also fills in the through hole 122. The insulating layer 24 in the first trench 20 and in the through hole 122 is formed by the same material. The insulating layer 24 may include silicon oxide, silicon nitride, silicon oxynitride or other insulating materials, and the insulating layer 24 may be formed by a single layer or a composite layer. The top surface of the insulating layer 24 of the TSV 50 and the top surface of the conductive layer 34 of the TSV 50 are both aligned with the front side 12 of the substrate 10. Moreover, the width of the through hole 122 is preferably larger than that of the first trench 20. More specifically speaking, the width of the through hole 122 is 3 times larger than that of the first trench 20. The semiconductive element with DTI and TSV 100 further comprises at least one STI 16 which extends from the front side 12 into the substrate 10. The STI 16 is shallower than the DTI 32. A circuit layer 36 may be disposed on the front side 12 of the substrate 10. The circuit layer 36 includes at least one transistor 40 and numerous contact plugs 44 disposed in an interlayer dielectric 42. Each contact plug 44 electrically connects to the transistor 44 or TSV 50, respectively. Additionally, a redistribution conductive layer 48 can be optionally positioned on the interlayer dielectric 42, and the redistribution conductive layer 48 connects electrically to the contact plugs 44. A pixel region 37 may be disposed in the substrate 10 and between two DTIs 32. At least one color filter 52 and at least one microlens 54 can be positioned on the back side 14 of the substrate 10 which corresponds to the pixel region 37.

The first trench of the DTI and the second trench of the TSV are both simultaneously formed by the single dry etch process. The insulating layer which functions as the insulating filling in the first trench also serves as a liner of the second trench. In other words, the insulating filling in the DTI and the liner in the TSV are formed by the same fabricating step. In this way, the fabricating steps of the semiconductive element with DTI and TSV 100 can be simplified, and the fabricating time is shortened.

Those skilled in the art will readily observe that numerous modifications and alterations of the device and method may be made while retaining the teachings of the invention. Accordingly, the above disclosure should be construed as limited only by the metes and bounds of the appended claims.

1. A method of forming a via and an isolating structure, comprising:
providing a substrate having a front side and a back side and at least one shallow trench isolation embedded in the substrate;
forming at least one first trench and at least one second trench both extending from the front side into the substrate;
forming an insulating layer filling up the first trench and conformally covering a sidewall and a bottom of the second trench;
forming a conductive layer in the second trench, wherein the conductive layer covers the insulating layer; and
thinning the back side of the substrate to expose the conductive layer through the back side so as to form a through silicon via.

2. The method of forming a via and an isolating structure of claim 1, wherein after the thinning step, the insulating layer in the first trench is exposed through the back side of the substrate.

3. The method of forming a via and an isolating structure of claim 1, wherein the first trench and the second trench are formed simultaneously by a single dry etch process.

4. The method of forming a via and an isolating structure of claim 3, wherein the first trench and the second trench are completed at the same time.

5. The method of forming a via and an isolating structure of claim 1, wherein the insulating layer is also disposed on the front side of the substrate.

6. The method of forming a via and an isolating structure of claim 1, wherein the conductive layer is only disposed in the second trench.

7. The method of forming a via and an isolating structure of claim 1, wherein the width of the second trench is larger than the width of the first trench.

8. The method of forming a via and an isolating structure of claim 1, wherein the insulating layer comprises silicon oxide, silicon nitride or silicon oxynitride.

9. The method of forming a via and an isolating structure of claim 1, wherein the conductive layer comprises metal, metal compound or doped polysilicon.

10. The method of forming a via and an isolating structure of claim 1, wherein after the insulating layer covers the second trench, a space is formed in the second trench and the conductive layer entirely fills the space.

11. A method of forming a via and an isolating structure, comprising:
providing a substrate having a front side and a back side;
forming at least one first trench and at least one second trench both extending from the front side into the substrate;
forming an insulating layer filling up the first trench and conformally covering a sidewall and a bottom of the second trench;
forming a conductive layer in the second trench, wherein the conductive layer covers the insulating layer;
forming a circuit layer on the front side of the substrate; and
thinning the back side of the substrate to expose the conductive layer through the back side to form a through silicon via.

12. The method of forming a via and an isolating structure of claim 11, wherein the step of forming the circuit layer comprises:
forming at least one transistor on the front side of the substrate;
forming a first interlayer dielectric covering the transistor and the front side of the substrate; and
forming at least two contact plugs in the first interlayer dielectric, wherein one of the contact plugs connects to the transistor and the other contact plug connects to the conductive layer.

13. The method of forming a via and an isolating structure of claim 12, further comprising:
after the circuit layer is formed, forming a second interlayer dielectric on the first interlayer dielectric; and
forming a redistribution conductive layer in the second interlayer dielectric and the redistribution conductive layer connecting to the contact plugs.

14. The method of forming a via and an isolating structure of claim 11, wherein the first trench and the second trench are formed simultaneously by a single dry etch process.

15. The method of forming a via and an isolating structure of claim 14, wherein the first trench and the second trench are completed at the same time.

16. The method of forming a via and an isolating structure of claim 11, wherein the insulating layer is also disposed on the front side of the substrate.

17. The method of forming a via and an isolating structure of claim 11, wherein the width of the second trench is larger than the width of the first trench.

18. The method of forming a via and an isolating structure of claim 11, wherein after the insulating layer covers the second trench, a space is formed in the second trench and the conductive layer entirely fills the space.
